(19) United States
(12) Patent Application Publication
(10) Pub. No.: US 2008/0247237 A1
(43) Pub. Date: Oct. 9, 2008

(54) SEMICONDUCTOR MEMORY DEVICE IN WHICH SENSE TIMING OF SENSE AMPLIFIER CAN BE CONTROLLED BY CONSTANT CURRENT CHARGE

(76) Inventor: Takumi Abe, Mountain View, CA (US)

Correspondence Address: OBLON, SPIVAK, MCCLELLAND MAIER & NEUSTADT, P.C., 1940 DUKE STREET, ALEXANDRIA, VA, 22314, US

(21) Appl. No.: 11/697,876

(22) Filed: Apr. 9, 2007

(51) Int. Cl. G11C 11/34

(52) U.S. Cl. 365/185.21

(57) ABSTRACT

A semiconductor memory device includes a plurality of sense amplifiers which read data from a plurality of memory cells of a memory cell array, and a sense time generation circuit which controls the sense time of the plurality of sense amplifiers, the sense time generation circuit including a dummy capacitor having substantially the same size as that of a capacitor provided in each of the plurality of sense amplifiers, a control transistor connected to one electrode of the dummy capacitor and a constant-current discharge circuit which controls the control transistor to discharge the dummy capacitor with a constant current. The constant-current discharge circuit includes first and second nMOS transistors which are connected in series and a mirror circuit which generates gate voltage to operate the first and second nMOS transistors in a saturated region by use of the lowest voltage.

### BACKGROUND OF THE INVENTION

This invention relates to a semiconductor memory device and more particularly to a NAND flash memory having memory cells configured by means of metal oxide semiconductor (MOS) transistors having a double (stacked) gate structure.

Conventionally, a NAND flash memory is well known as a nonvolatile semiconductor memory device which can electrically rewrite (write and erase) data and is suitable for achieving high integration density and large capacity. Further, the NAND flash memory which has a sense amplifier capable of controlling sense time (STB pulse width or discharging time in which the capacitance of a sense node is discharged by use of a cell current) is proposed (for example, refer to U.S. Pat. No. 7,023,736).

As the sense system of the sense amplifier used in the NAND flash memory, a method for setting sense time to a fixed value specified by a circuit is provided. Further, as one method for compensating for a variation in the sense characteristic due to the temperature dependency of transistors configuring the sense amplifier, a method for controlling the sense time is provided.

As a method for controlling the sense time of the sense amplifier, a method using a dummy sense amplifier is considered. The method is to prepare a dummy sense amplifier with the same configuration as that of the original (actual) sense amplifier and discharge the dummy capacitor with the same capacitance as that of the capacitor of the original sense amplifier with a constant current by use of a constant-current discharge circuit. Then, the sense time of the original sense amplifier is controlled according to time until the dummy transistor (for example, pMOS transistor) which is supplied with voltage of the sense node is turned on by the constant-current discharging operation.

With the above method, it is necessary to continuously discharge the dummy capacitor with the constant current until the dummy transistor which is supplied with the voltage of the sense node is turned on. Therefore, the constant-current discharge circuit is required to have the ability of continuously discharging the dummy capacitor with the constant current even when internal operation voltage of the device is set at a certain low voltage level. The requirement becomes stronger as the internal operation voltage is further lowered. Particularly, when the initial charging level of the capacitor and the source potential of the pMOS transistor of the original sense amplifier are lowered, the gate voltage level required for turning on the dummy transistor is lowered accordingly. Therefore, the constant-current discharge circuit is required to have the ability of discharging the dummy capacitor with the constant current until a lower voltage level is attained. That is, it is necessary to generate lower gate potential in order to turn on the dummy transistor whose source potential is lowered.

As described above, in the NAND flash memory, an attempt is made to lower the internal operation voltage. Therefore, it is required to develop a constant-current discharge circuit capable of discharging the dummy capacitor to a lower voltage level with a constant current in order to compensate for a variation in the sense characteristic due to the temperature dependency of transistors configuring the sense amplifier.

### BRIEF SUMMARY OF THE INVENTION

According to a first aspect of the present invention, there is provided a semiconductor memory device comprising a memory cell array including a plurality of memory cells, a plurality of sense amplifiers which read data from the plurality of memory cells of the memory cell array, and a sense time generation circuit which controls sense time of the plurality of sense amplifiers, the sense time generation circuit including a dummy capacitor having substantially the same size as that of a capacitor provided in each of the plurality of sense amplifiers, a control transistor connected to one electrode of the dummy capacitor and a constant-current discharge circuit which controls the control transistor to discharge the dummy capacitor with a constant current, wherein the constant-current discharge circuit includes first and second n-type metal oxide semiconductor (nMOS) transistor which are connected in series and a mirror circuit which generates gate voltage to operate the first and second nMOS transistors in a saturated region by use of the lowest voltage.

According to a second aspect of the present invention, there is provided a semiconductor memory device comprising a memory cell array including a plurality of memory cells, a plurality of sense amplifiers which read data from the plurality of memory cells of the memory cell array, and a sense time generation circuit which controls sense time of the plurality of sense amplifiers, the sense time generation circuit including a dummy capacitor having substantially the same size as that of a capacitor provided in each of the plurality of sense amplifiers, a control transistor connected to one electrode of the dummy capacitor and a constant-current discharge circuit which controls the control transistor to discharge the dummy capacitor with a constant current, wherein the constant-current discharge circuit includes a first n-type metal oxide semiconductor (nMOS) transistor having a drain connected to the source of the control transistor, a second n-type metal oxide semiconductor (nMOS) transistor having a drain connected to the source of the first nMOS transistor, a first current source connected to the gate of the first nMOS transistor, a second current source connected to the gate of the second nMOS transistor, a third nMOS transistor whose gate and drain are supplied with an output of the first current source, a fourth nMOS transistor whose gate is supplied with the output of the first current source and whose drain is supplied with an output of the second current source, and a fifth nMOS transistor whose gate is supplied with the output of the second current source.

### BRIEF DESCRIPTION OF THE SEVERAL VIEWS OF THE DRAWING

FIG. 1 is a block diagram showing an example of the configuration of a NAND flash memory according to a first embodiment of this invention.

FIG. 2 is a diagram of the configuration showing an extracted portion of a core portion of the NAND flash memory.

FIG. 3 is a block diagram showing an example of the configuration of a control section which controls the sense time of a sense amplifier.

FIG. 4 is a circuit diagram showing an example of the configuration of a sense timing generator which configures the control section of FIG. 3.

FIG. 5 is a timing chart for illustrating the operation of the sense timing generator.

FIG. 6 is a circuit diagram showing an example of the configuration of a constant-current discharge circuit.

FIG. 7 is a waveform diagram for illustrating the operation characteristic of the constant-current discharge circuit.

### DETAILED DESCRIPTION OF THE INVENTION

Embodiments of the present invention will be described with reference to the accompanying drawings. It should be noted that the drawings are schematic ones and the dimension ratios shown therein are different from the actual ones. The dimensions vary from drawing to drawing and so do the ratios of the dimensions. The following embodiments are directed to a device and a method for embodying the technical concept of the present invention and the technical concept does not specify the material, shape, structure or configuration of components of the present invention. Various changes and modifications can be made to the technical concept without departing from the spirit or scope of the claimed invention.

### First Embodiment

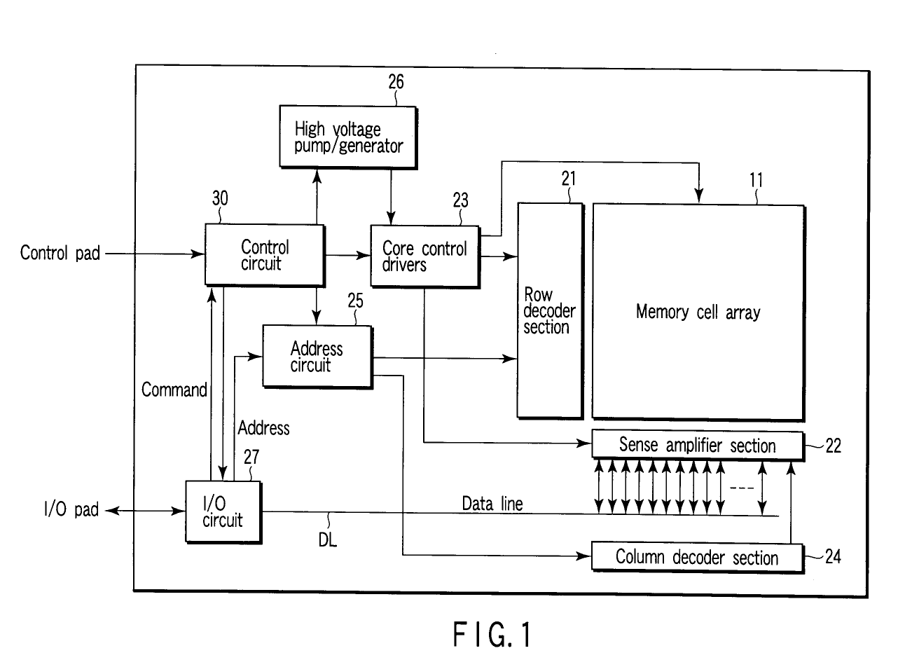

FIG. 1 shows the basic configuration of a semiconductor memory device according to a first embodiment of this invention. The present embodiment is explained by taking a NAND flash memory having memory cells configured by MOS transistors with the double-gate structure which is a nonvolatile semiconductor memory device as an example.

As shown in FIG. 1, the memory chip includes a memory cell array 11, row decoder 21, sense amplifier section 22, core control drive section 23, column decoder section 24, address circuit 25, high-voltage generation circuit 26, input/output (I/O) circuit 27 and control circuit 30. The memory cell array 11 includes a plurality of memory cell transistors and stores write data in a nonvolatile fashion. The memory cell array 11 is explained in detail later. The row decoder section 21 is supplied with a block selection signal from the address circuit 25 and selects a block corresponding to the block selection signal from the memory cell array 11. Then, it applies adequate potential corresponding to the operation to the word line of the selected block.

The sense amplifier section 22 includes a plurality of sense amplifiers (S/A) and reads the state (held data) of a selected cell transistor. The core control drive section 23 is a driver circuit which controls the core section of the memory chip and supplies control signals (control pulses) corresponding to the operation and adequate voltages corresponding to the operation to the memory cell array 11, row decoder section 21 and sense amplifier section 22. The column decoder section 24 controls connection between a data line DL and a column (sense amplifier S/A) selected by the memory cell array 11 according to a column selection signal from the address circuit 25 and transfers read data and write data between the input/output circuit 27 and the sense amplifier S/A. The address circuit 25 generates a block selection signal and column selection signal according to the operation and address information input from the exterior of the chip and respectively supplies the block selection signal and column selection signal to the row decoder section 21 and column decoder section 24.

The high-voltage generation circuit 26 includes a charge pump circuit, generates voltage corresponding to the operation according to an instruction from the control circuit 30 and supplies the thus generated voltage to the control drive section 23. The input/output circuit 27 fetches a command, address information and write data input from the I/O pads of the chip at the write operation time according to an instruction from the control circuit 30 and respectively outputs the command, address information and write data to the control circuit 30, address circuit 25 and data line DL. Further, it outputs read data on the data line DL to the I/O pad according to an instruction from the control circuit 30 at the read operation time. The control circuit 30 is configured to include a sense time generation circuit which will be described later and controls the core control drive section 23, address circuit 25, high-voltage generation circuit 26 and input/output (I/O) circuit 27 in response to a control signal input from the exterior of the chip. In this case, write data is written into the cell transistor and used as held data and the held data is read from the cell transistor and used as read data.

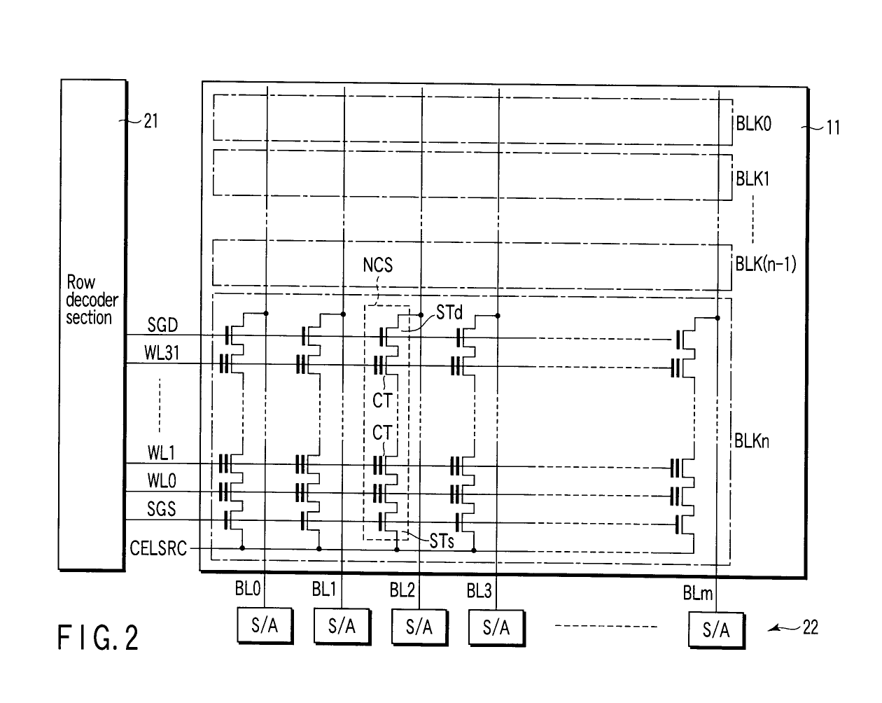

FIG. 2 shows the configuration of the core portion of the memory chip described above. In the case of the present embodiment, for example, NAND cell strings (NAND strings) NCS each include 32 memory cell transistors CT connected in series and selection transistors STd and STs connected to both ends of the series connected memory cell transistors. The NAND cell string NCS is a constituent unit of the memory cell array 11. Each of the memory cell transistors CT is configured by a MOS transistor with the double-gate structure. The control gate electrode of the memory cell transistor CT is connected to a corresponding one of word lines WL0 to WL31.

The selection transistor STd arranged on one side of the NAND cell string NCS is connected to a corresponding one of bit lines BL0 to BLm. The gate electrodes of the selection transistors STd are commonly connected to a selection signal line SGD. The selection transistors STs arranged on the other sides of the NAND cell strings NCS are commonly connected to a source line (CELSRC). The gate electrodes of the selection transistors STs are commonly connected to a selection signal line SGS. The word lines WL0 to WL31 and selection signal lines SGD, SGS are connected to the row decoder 21. The bit lines BL0 to BLm are respectively connected to the sense amplifiers S/A. Each block (unit) BLK0 to BLKn is configured by the m NAND cell strings NCS which commonly use the word lines WL0 to WL31 and selection signal lines SGD, SGS.

That is, the memory cell array 11 includes the n blocks BLK0 to BLKn. In each of the blocks BLK0 to BLKn, the m NAND cell strings NCS commonly using the bit lines BL0 to BLm are provided. The m NAND cell strings NCS of each of the blocks BLK0 to BLKn commonly use the word lines WL0 to WL31 and selection signal lines SGD, SGS.

The data write and erase operations are performed by injecting or discharging electrons by use of an FN tunnel current with respect to the floating gate electrode of the selected memory cell transistor CT.

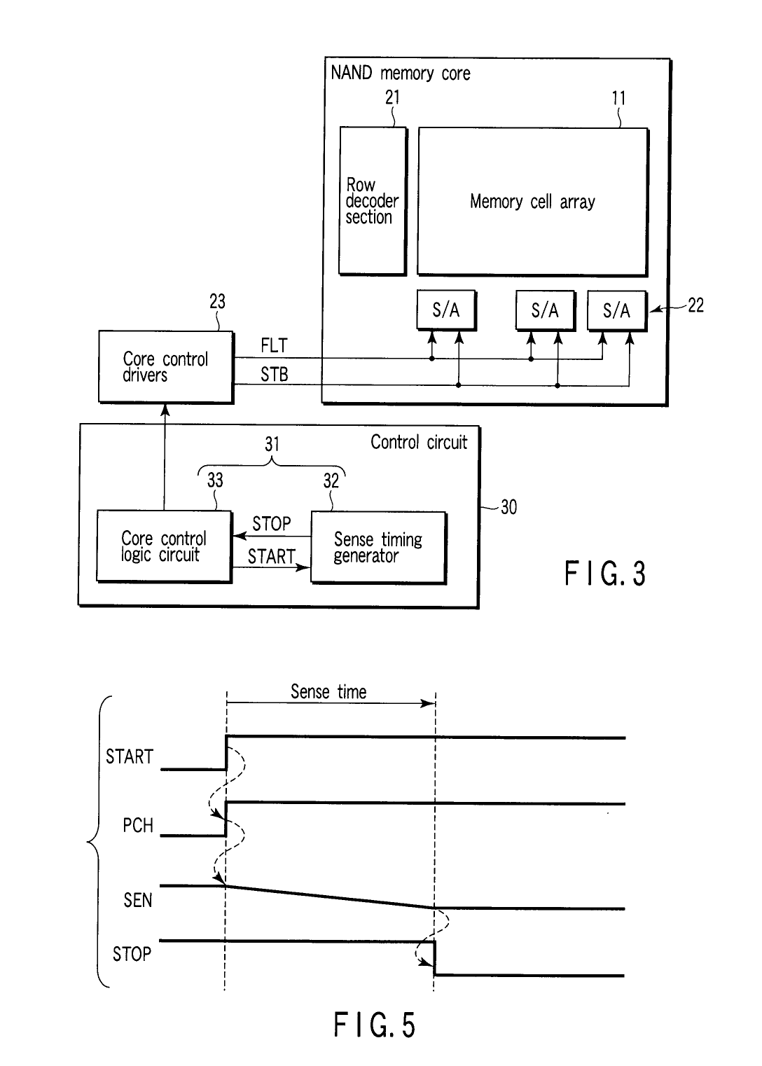

FIG. 3 shows the configuration of a sense time generation circuit (control section) which controls the sense time of the sense amplifier. In the case of the present embodiment, the sense time generation circuit 31 is provided in the control circuit 30. The sense time generation circuit 31 includes a sense timing generator 32 and core control logic circuit 33.

The sense timing generator 32 generates a STOP pulse according to a START pulse from the core control logic circuit 33 and outputs the STOP pulse to the core control logic circuit 33. The core control logic circuit 33 controls the core control drive section 23 in response to the START pulse and the STOP pulse from the sense timing generator 32. That is, the core control logic circuit 33 generates an FLT pulse and STB pulse to control each of the sense amplifiers S/A of the sense amplifier section 22 based on the START pulse and the STOP pulse from the sense timing generator 32 and supplies the pulses to the core control drive section 23.

The configuration of the sense amplifier S/A and the time control operation of the sense amplifier S/A are disclosed in U.S. Pat. No. 7,023,736, for example, and therefore, the detail explanation thereof is omitted here.

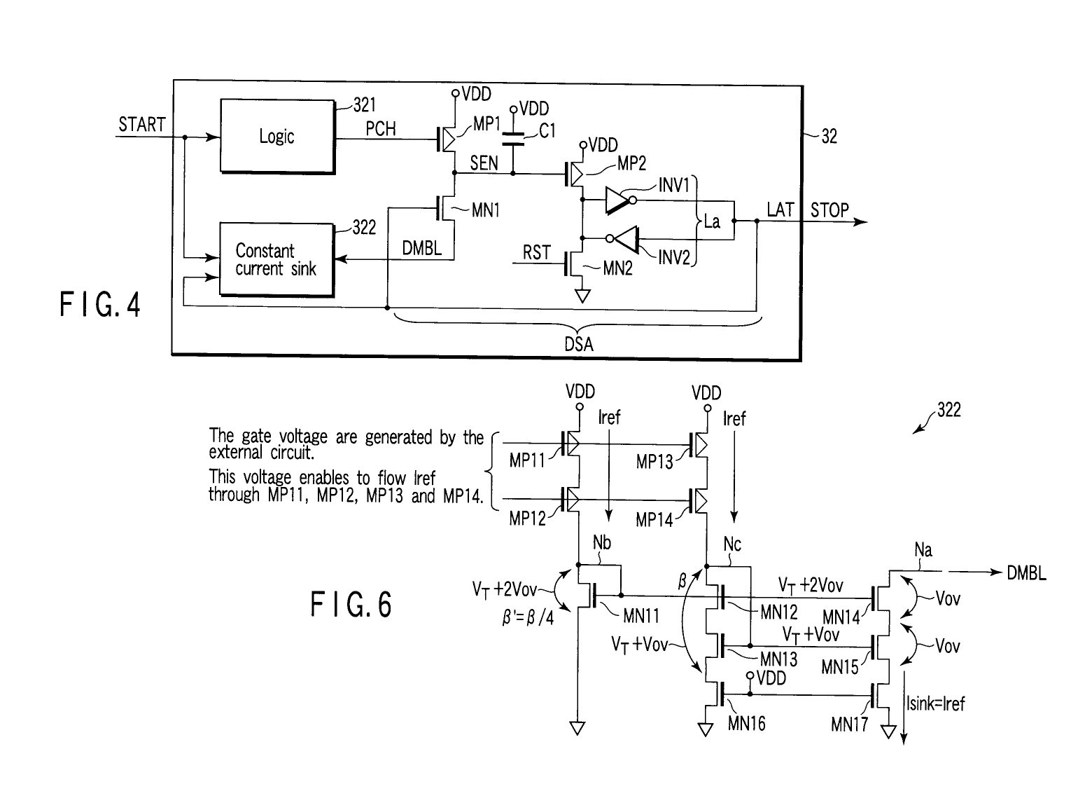

FIG. 4 shows an example of the configuration of the sense timing generator 32 configuring the sense time generation circuit 31. The sense timing generator 32 includes a dummy sense amplifier DSA having substantially the same configuration as the sense amplifier S/A, logic circuit 321 and constant-current discharge (sink) circuit 322.

The logic circuit 321 detects a rise of the START pulse from the core control logic circuit 33 and generates a high-level gate pulse PCH. The constant-current discharge circuit 322 discharges a dummy capacitor C1 provided in the dummy sense amplifier DSA with a constant current at the sense time. The dummy sense amplifier DSA includes p-type MOS (pMOS) transistors MP1, MP2 (dummy transistors), n-type MOS (nMOS) transistors MN1, MN2, a dummy capacitor C1 having the same value (capacitance) as a capacitor (not shown) provided in the sense amplifier S/A, and a latch circuit La formed of inverter circuits INV1, INV2.

That is, the gate of the pMOS transistor MP1 is connected to the logic circuit 321 and the source thereof is supplied with the internal operation voltage VDD of the memory chip. The drain of the pMOS transistor MP1 is connected to the drain of the nMOS transistor MN1. The source of the nMOS transistor MN1 is connected to the discharging path (DMLB) of the constant-current discharge circuit 322. The gate of the pMOS transistor MP2 and one of the electrodes of the capacitor C1 are connected to the common drain (sense node SEN) of the pMOS transistor MP1 and nMOS transistor MN1. The other electrode of the capacitor C1 and the source of the pMOS transistor MP2 are supplied with the internal operation voltage VDD. The drain of the pMOS transistor MP2 is connected to the drain of the nMOS transistor MN2. The gate of the nMOS transistor MN2 is connected to a reset (RST) terminal (not shown) and the source thereof is grounded (connected to a ground potential node VSS).

In the latch circuit La, the input terminal of the inverter INV1 and the output terminal of the inverter INV2 are connected to the common drain of the pMOS transistor MP2 and nMOS transistor MN2. The output terminal of the inverter INV1 and the input terminal of the inverter INV2 which are an output node (node LAT) of the latch circuit La are connected to the gate of the nMOS transistor MN1 and constant-current discharge circuit 322. Further, the output of the latch circuit La is taken out to the exterior as an output (STOP pulse) of the sense timing generator 32. The logic circuit 321 and constant-current discharge circuit 322 are supplied with the START pulse from the core control logic circuit 33.

FIG. 5 illustrates the operation of the sense timing generator 32. For example, it is supposed that the START pulse from the core control logic circuit 33 goes high. Then, the logic circuit 321 generates a high-level gate pulse PCH to control the gate of the pMOS transistor MP1. As a result, the pMOS transistor MP1 is turned off. At this time, the STOP pulse supplied to the gate is made high to turn the nMOS transistor MN1 on. Thus, the dummy capacitor C1 is discharged with a constant current by the discharging path (DMBL) of the constant-current discharge circuit 322 via the sense node SEN and nMOS transistor MN1.

After a while, when the potential of the sense node SEN is gradually lowered and reaches the threshold voltage of the pMOS transistor MP2, the pMOS transistor MP2 is turned on. Then, the output of the latch circuit La is inverted. Further, the STOP pulse is made low and the nMOS transistor MN1 is turned off. Therefore, the constant-current discharging operation for the capacitor C1 by the constant-current discharge circuit 322 is terminated. Thus, the sense time optimum for compensating for a variation in the sense characteristic due to the temperature dependency of transistors configuring the sense amplifier S/A can be indirectly acquired by the sense timing generator 32. That is, according to the sense timing generator 32, a time period from the time when the pMOS transistor MP1 is turned off to the time when the pMOS transistor MP2 is turned on by the constant-current discharging operation is derived as optimum sense time.

In the case of the present embodiment, the core control logic circuit 33 generates an FLT pulse (high level) based on the fall of the START pulse and generates an STB pulse (low level) based on the fall of the STOP pulse. Thus, the FLT pulse and STB pulse which are used to drive the sense amplifiers S/A of the sense amplifier section 22 by use of the optimum sense time are obtained.

In this case, the constant-current discharge circuit 322 is required to have the ability of discharging the dummy capacitor C1 with a constant current to a lower voltage level. For example, the constant-current discharge circuit 322 is designed to continuously discharge the dummy capacitor with the constant current until the pMOS transistor MP2 is turned on when the voltage level at which the pMOS transistor MP2 is turned on is lowered by a lowering in the internal operation voltage (VDD) of the memory chip or a lowering in the initial charging level of the capacitor of the sense amplifier S/A and a lowering in the source potential of the pMOS transistor MP2.

FIG. 6 showing an example of the configuration of the constant-current discharge circuit 322. The constant-current discharge circuit 322 of the present embodiment is a current mirror circuit and configured to mirror reference currents Iref flowing through pMOS transistors MP11, MP12 and pMOS transistors MP13, MP14 by use of an nMOS transistor MN11 and nMOS transistors MN12, MN13 and cause a discharge current Isink (=Iref) to flow through nMOS transistors MN14, MN15. In the following explanation, in order to facilitate the understanding, a case wherein the nMOS transistors MN11 to MN15 are formed with the same size (the threshold voltage V_{T} is set constant) is explained.

That is, the drain of the PMOS transistor MP11 is connected to the source of the pMOS transistor MP12. The source of the pMOS transistor MP11 is supplied with the internal operation voltage VDD. The drain of the pMOS transistor MP12 is connected to the drain and gate of the diode-connected nMOS transistor MN11. The source of the nMOS transistor MN11 is grounded. Likewise, the drain of the pMOS transistor MP13 is connected to the source of the pMOS transistor MP14. The source of the pMOS transistor MP13 is supplied with the internal operation voltage VDD.

The drain of the pMOS transistor MP14 is connected to the drain of the nMOS transistor MN12 and the gates of the nMOS transistors MN13, MN15. The source of the nMOS transistors MN12 is connected to the drain of the nMOS transistor MN13. The gate of the nMOS transistor MN12 is connected to the gate and drain of the nMOS transistor MN11 and the gate of the nMOS transistor MN14. The source of the nMOS transistor MN14 is connected to the drain of the nMOS transistor MN15 and the drain thereof forms a discharge path (DMLB) connected to the source of the nMOS transistor MN1.

The source of the nMOS transistor MN13 is grounded via an nMOS transistor MN16 and source of the nMOS transistor MN15 is grounded via an nMOS transistor MN17. The gates of the nMOS transistors MN16, MN17 are supplied with the internal operation voltage VDD and they function as switches. Further, the gates of the pMOS transistors MP11, MP12, MP13, MP14 are connected to a circuit (not shown) which generates gate voltage. By controlling the circuit by use of the START pulse and STOP pulse, the reference currents Iref are passed through the pMOS transistor MP11, MP12 and pMOS transistor MP13, MP14.

In order to discharge the dummy capacitor C1 with a constant current to a lower voltage level in the constant-current discharge circuit 322, it is necessary to operate the nMOS transistors MN14, MN15 in the pentode operation mode (operated in the saturated region). For this purpose, voltage of the node Na must be set to 2 Vov or more. In this case, Vov indicates the lowest voltage to permit the nMOS transistors MN14, MN15 to be operated in the saturated region and is given by the following expressions (1) to (4).

$$\begin{matrix}{V}_{DS} \geq {V}_{GS} - {V}_{T} ( Saturation Condition ) & ( 1 ) \\ {I}_{ref} = \frac{β}{2} {( {V}_{GS} - {V}_{T} )}^{2} & ( 2 ) \\ {V}_{GS} = {V}_{T} + \sqrt{\frac{2 {I}_{ref}}{β}} & ( 3 ) \\ {V}_{OV} ≡ \sqrt{\frac{2 {I}_{ref}}{β}} & ( 4 )\end{matrix}$$

where V_{DS} indicates the source-drain voltage of the nMOS transistor, V_{GS} indicates the source-gate voltage of the nMOS transistor, and β, β′ indicate the aspect ratios (gate widths) of the nMOS transistors.

That is, the constant-current discharge circuit 322 is designed to permit the nMOS transistors MN14, MN15 to be operated by use of the lowest voltage Vov when the nMOS transistors MN14, MN15 are operated in the saturated region. For this purpose, the size (aspect ratio β′) of the nMOS transistor MN11 which generates the gate voltage of the nMOS transistor MN12 is set to ¼ the size (β) of the nMOS transistor MN12. Therefore, the lowest voltage Vov used to operate the nMOS transistor MN11 in the saturated region is set to twice the lowest voltage Vov used to operate the nMOS transistor MN12 in the saturated region. As a result, the voltage of the node Nb is set to (V_{T}+2 Vov) (the voltage of the node Nc is set to V_{T}+Vov). Therefore, the gate voltage of the nMOS transistor MN14 connected to the discharge path (DMBL) is set to (V_{T}+2 Vov) and the gate voltage of the nMOS transistor MN15 is set to (V_{T}+Vov). As a result, the source-drain voltages of the nMOS transistors MN14, MN15 are set to Vov. Therefore, the two nMOS transistors MN14, MN15 can be operated in the saturated region. That is, even when the drain voltage (the voltage of the node Na) of the nMOS transistor MN14 is lowered to 2 Vov which is the sum of the source-drain voltages of the two nMOS transistors MN14, MN15, the discharge path (DMBL) can be operated in the saturated region.

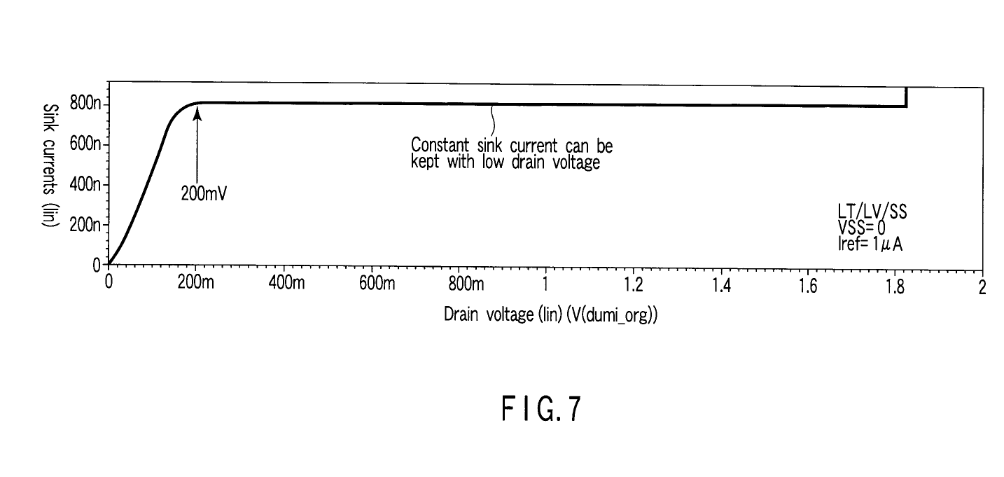

With the configuration of the present embodiment, for example, a case wherein the transistor characteristics of the nMOS transistors MN11 to MN15 are set with V_{T}=0.7 V and Vov=0.1 V is considered below. In the case of the constant-current discharge circuit 322, for example, as shown in FIG. 7, the operation characteristic set to attain the constant-current discharging operation can be maintained until the voltage of the sense node SEN is lowered to approximately 0.2 V. This is because the lowest voltage at which the nMOS transistors MN14, MN15 are operated in the saturated region is set to 0.2 V. Thus, even if the internal operation voltage VDD is lowered and the initial charge level of the sense node SEN is lowered, the capacitor C1 can be continuously discharged with a constant current until the voltage is lowered to approximately 0.2 V. In short, if the internal operation voltage VDD is lowered from 3 to 2 V, the MOS transistor designed for 3-V operation can be stably operated without changing the characteristic thereof and the capacitor C1 can be continuously discharged with a constant current to a lower voltage level.

As described above, the constant-current discharge circuit of the present embodiment is designed to discharge the dummy capacitor with the constant current to a lower voltage level. That is, the constant-current discharge circuit is configured to set the lowest voltage which permits the nMOS transistor connected to the discharge path to be operated in the saturated region as low as possible. Therefore, the dummy capacitor can be kept discharged with a constant current until the dummy transistor is turned on even if the voltage of the sense node is lowered. Thus, the dummy capacitor can be discharged with the constant current to a lower voltage level when the sense time of the sense amplifier is controlled by use of the dummy capacitor in order to compensate for a variation in the sense characteristic due to the temperature dependency of the transistors configuring the sense amplifier. As a result, in the NAND flash memory, the controllability of the sense time of the sense amplifier can be significantly enhanced.

Particularly, according to the constant-current discharge circuit of the present embodiment, the dummy capacitor can be discharged with the constant current to a lower voltage level without redesigning the MOS transistors according to a lowering in the voltage when the internal operation voltage is lowered.

In the first embodiment described above, a case wherein the threshold voltages VT of the nMOS transistors MN11 to MN15 of the constant-current discharge circuit 322 are set constant is explained for convenience sake. However, this invention is not limited to this case and can be applied to a constant-current discharge circuit configured by nMOS transistors having different threshold voltages V_{T}, for example.

Further, the aspect ratio β′ of the nMOS transistor MN11 is not limited to ¼ the aspect ratio of the nMOS transistor MN12 and may be set to any value if it is smaller than the aspect ratio of the nMOS transistor MN12.

The power supply voltage applied to one end of the dummy capacitor C1 is not limited to the internal operation voltage VDD.

Further, the size of the dummy capacitor C1 is not necessarily set equal to the size of the capacitor provided in the sense amplifier S/A. For example, with the configuration shown in FIG. 4, when the dummy capacitor C1 is discharged with a constant current, the charge amount q is obtained as follows if the capacitance of the dummy capacitor C1 is C, the voltage required for turning on the pMOS transistor MP2 is V, the discharge current is I and the discharge time is t.

q=CV=It

Therefore, the following equation can be attained.

t=CV/I

That is, C/I may be controlled in order to adjust the discharge time t. Therefore, for example, when the size of the dummy capacitor C1 is set to twice the size of the capacitor provided in the sense amplifier S/A, the same discharge time t can be attained by doubling the discharge current I.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a memory cell array including a plurality of memory cells,
a plurality of sense amplifiers which read data from the plurality of memory cells of the memory cell array, and
a sense time generation circuit which controls sense time of the plurality of sense amplifiers, the sense time generation circuit including a dummy capacitor having substantially the same size as that of a capacitor provided in each of the plurality of sense amplifiers, a control transistor connected to one of electrodes of the dummy capacitor and a constant-current discharge circuit which controls the control transistor to discharge the dummy capacitor with a constant current,
wherein the constant-current discharge circuit includes first and second n-type metal oxide semiconductor (nMOS) transistor which are connected in series and a mirror circuit which generates gate voltage to operate the first and second nMOS transistors in a saturated region by use of lowest voltage.

2. The semiconductor memory device according to claim 1, wherein the dummy capacitor is applied at the other electrode with operation voltage of the device and discharged with a constant current at sense time.

3. The semiconductor memory device according to claim 1, wherein a drain of the first nMOS transistor of the sense time generation circuit is connected to a source of the control transistor and a source of the first nMOS transistor is connected to a drain of the second nMOS transistor.

4. The semiconductor memory device according to claim 1, wherein the mirror circuit includes a first current source, a second current source, a third nMOS transistor whose gate and drain are supplied with an output of the first current source, a fourth nMOS transistor whose gate is supplied with the output of the first current source and whose drain is supplied with an output of the second current source, and a fifth nMOS transistor whose gate is supplied with the output of the second current source.

5. The semiconductor memory device according to claim 4, wherein the third nMOS transistor is diode-connected.

6. The semiconductor memory device according to claim 4, wherein an aspect ratio of the third nMOS transistor is set to ¼ that of the fourth nMOS transistor.

7. The semiconductor memory device according to claim 1, wherein the mirror circuit includes a first current source, a second current source, a third nMOS transistor whose gate and drain are supplied with an output of the first current source, a fourth nMOS transistor whose gate is supplied with the output of the first current source and whose drain is supplied with an output of the second current source, a fifth nMOS transistor whose gate is supplied with the output of the second current source, the output of the first current source is supplied to the gate of the first nMOS transistor, and the output of the second current source is supplied to the gate of the second nMOS transistor.

8. The semiconductor memory device according to claim 7, wherein a discharge current equivalent to the output of the first current source and the output of the second current source is passed through the first and second nMOS transistors when threshold voltages of the first, second, third, fourth and fifth nMOS transistors are set to VT and an aspect ratio of the third nMOS transistor is set to ¼ that of the fourth nMOS transistor.

9. The semiconductor memory device according to claim 7, wherein lowest voltage for operating the first and second nMOS transistors in a saturated region is applied between the source and drain of the first and second nMOS transistors when threshold voltages of the first, second, third, fourth and fifth nMOS transistors are set to VT and an aspect ratio of the third nMOS transistor is set to ¼ that of the fourth nMOS transistor.

10. The semiconductor memory device according to claim 1, wherein the plurality of memory cells are MOS transistors with a stacked gate structure in which data is written and erased by use of an FN tunnel current and connected for every preset number to form NAND cell strings.

11. The semiconductor memory device according to claim 1, wherein the sense time generation circuit includes the first nMOS transistor whose drain is connected to a source of the control transistor, the second nMOS transistor whose drain is connected to a source of the first nMOS transistor, a first current source connected to a gate of the first nMOS transistor, a second current source connected to a gate of the second nMOS transistor, a third nMOS transistor whose gate and drain are supplied with an output of the first current source, a fourth nMOS transistor whose gate is supplied with the output of the first current source and whose drain is supplied with an output of the second current source, and a fifth nMOS transistor whose gate is supplied with the output of the second current source.

12. A semiconductor memory device comprising:
a memory cell array including a plurality of memory cells,
a plurality of sense amplifiers which read data from the plurality of memory cells of the memory cell array, and
a sense time generation circuit which controls sense time of the plurality of sense amplifiers, the sense time generation circuit including a dummy capacitor having substantially the same size as that of a capacitor provided in each of the plurality of sense amplifiers, a control transistor connected to one of electrodes of the dummy capacitor and a constant-current discharge circuit which controls the control transistor to discharge the dummy capacitor with a constant current,
wherein the constant-current discharge circuit includes a first n-type metal oxide semiconductor (nMOS) transistor having a drain connected to a source of the control transistor, a second n-type metal oxide semiconductor (nMOS) transistor having a drain connected to a source of the first nMOS transistor, a first current source connected to a gate of the first nMOS transistor, a second current source connected to a gate of the second nMOS transistor, a third nMOS transistor whose gate and drain are supplied with an output of the first current source, a fourth nMOS transistor whose gate is supplied with the output of the first current source and whose drain is supplied with an output of the second current source, and a fifth nMOS transistor whose gate is supplied with the output of the second current source.

13. The semiconductor memory device according to claim 12, wherein the dummy capacitor is applied at the other electrode with operation voltage of the device and discharged with a constant current at sense time.

14. The semiconductor memory device according to claim 12, wherein the output from the first current source is equal to the output from the second current source.

15. The semiconductor memory device according to claim 12, wherein the third nMOS transistor is diode-connected.

16. The semiconductor memory device according to claim 12, wherein an aspect ratio of the third nMOS transistor is set to ¼ that of the fourth nMOS transistor.

17. The semiconductor memory device according to claim 12, wherein a discharge current equivalent to the output of the first current source and the output of the second current source is passed through the first and second nMOS transistors when threshold voltages of the first, second, third, fourth and fifth nMOS transistors are set to VT, an aspect ratio of the third nMOS transistor is set to ¼ that of the fourth nMOS transistor and the output from the first current source is equal to the output from the second current source.

18. The semiconductor memory device according to claim 12, wherein lowest voltage for operating the first and second nMOS transistors in a saturated region is applied between the source and drain of the first and second nMOS transistors when threshold voltages of the first, second, third, fourth and fifth nMOS transistors are set to VT, an aspect ratio of the third nMOS transistor is set to ¼ that of the fourth nMOS transistor and the output from the first current source is equal to the output from the second current source.

19. The semiconductor memory device according to claim 12, wherein the plurality of memory cells are MOS transistors with a stacked gate structure in which data is written and erased by use of an FN tunnel current and connected for every preset number to form NAND cell strings.
